(19) United States
(12) Patent Application Publication
(10) Pub. No.: US 2015/0332914 A1
(43) Pub. Date: Nov. 19, 2015

(54) SEMICONDUCTOR SUBSTRATE, METHOD OF MANUFACTURING SEMICONDUCTOR SUBSTRATE, AND SEMICONDUCTOR DEVICE

(71) Applicant: NuFlare Technology, Inc., Kanagawa (JP)

(72) Inventors: Takumi YAMADA, Kanagawa (JP); Yuusuke SATO, Tokyo (JP)

(21) Appl. No.: 14/709,530

(22) Filed: May 12, 2015

(30) Foreign Application Priority Data
May 13, 2014 (JP) 2014-099628

(51) Int. Cl. H01L 21/02; H01L 29/20

(52) U.S. Cl. CPC H01L 21/0254; H01L 29/2003; H01L 21/02381; H01L 21/02488; H01L 21/02598

(57) ABSTRACT

A semiconductor substrate according to embodiments includes a silicon substrate, a silicon nitride layer on the silicon substrate, the silicon nitride layer having a thickness of 1 nm or thicker, single-crystal aluminum nitride layer on the silicon nitride layer, and a single-crystal layer on the aluminum nitride layer, the single-crystal layer containing gallium (Ga).

### CROSS-REFERENCE TO RELATED APPLICATION

This application is based upon and claims the benefit of priority from Japanese Patent Applications No. 2014-099628, filed on May 13, 2014, the entire contents of which are incorporated herein by reference.

### FIELD

The present disclosure relates to a semiconductor substrate having a single-crystal layer containing gallium formed on a silicon substrate, a method of manufacturing a semiconductor substrate, and a semiconductor device.

### BACKGROUND

One of the methods of forming high-quality semiconductor layers is epitaxial growth technology of growing a single-crystal layer by vapor phase growth on a substrate such as a wafer. In epitaxial growth technology, a process gas such as a source gas to be a material of the layer to be formed is supplied onto the surface of a wafer while the wafer is being heated. A thermal reaction of the source gas occurs on the surface of the wafer and an epitaxial single-crystal layer is formed on the surface of the wafer.

Recently, gallium nitride (GaN) based semiconductor is drawing attention as a material for light emitting devices or power devices. The epitaxial growth technology for forming GaN based semiconductor layers includes the metal organic chemical vapor deposition method (MOCVD method).

It is known that growth of a high-quality single-crystal GaN based semiconductor layer on a silicon (Si) substrate is difficult. This is considered due to reaction between silicon and gallium.

To deal with this situation, JP-A 2006-261476 describes a method of forming a buffer layer of aluminum nitride (AlN) on a silicon substrate. Further, JP-A 2012-164717 describes a method of forming an aluminum gallium nitride layer after forming a two or less atom-thick silicon nitride layer on a silicon substrate. A thick silicon nitride layer may pose difficulty in growing aluminum nitride layer or inability to grow a single-crystal aluminum nitride layer on the silicon nitride layer.

### SUMMARY

A semiconductor substrate according to one embodiment of the present invention includes: a silicon substrate; a silicon nitride layer disposed on the silicon substrate, the silicon nitride layer having a thickness of 1 nm or thicker; single-crystal aluminum nitride layer disposed on the silicon nitride layer; and a single-crystal layer disposed on the aluminum nitride layer, the single-crystal layer containing gallium (Ga).

A semiconductor device according to one embodiment of the present invention includes: a silicon substrate; a silicon nitride layer disposed on the silicon substrate, the silicon nitride layer having a thickness of 1 nm or thicker; single-crystal aluminum nitride layer disposed on the silicon nitride layer; and a single-crystal layer disposed on the aluminum nitride layer, the single-crystal layer containing gallium (Ga).

A method of manufacturing a semiconductor substrate according to one embodiment of the present invention includes: forming single-crystal aluminum nitride layer on a silicon substrate; nitriding the silicon substrate to forma silicon nitride layer between the aluminum nitride layer and the silicon substrate, the silicon nitride layer having a thickness of 1 nm or thicker; and forming a single-crystal layer containing gallium (Ga) on the aluminum nitride layer.

### BRIEF DESCRIPTION OF THE DRAWINGS

FIG. 1 is a schematic cross-sectional view of a semiconductor substrate according to a first embodiment.

FIG. 2 is a process flow diagram of a first manufacturing method according to the first embodiment.

FIGS. 3A to 3C are schematic cross-sectional views of the first manufacturing method according to the first embodiment.

FIG. 4 is a process flow diagram of a second manufacturing method according to the first embodiment.

FIGS. 5A to 5C are schematic cross-sectional views of the second manufacturing method according to the first embodiment.

FIG. 6 is a schematic cross-sectional view of a semiconductor substrate according to a second embodiment.

FIG. 7 is a process flow diagram of a manufacturing method according to the second embodiment.

FIGS. 8A to 8C are schematic cross-sectional views of the manufacturing method according to the second embodiment.

FIG. 9 is a schematic cross-sectional view of a semiconductor device according to a third embodiment.

FIGS. 10A and 10B are cross-sectional transmission electron microscope (TEM) photographs of Example and Comparative Example.

### DETAILED DESCRIPTION

Embodiments of the present invention are described below with reference to the drawings.

### First Embodiment

A semiconductor substrate according to a first embodiment includes a silicon (Si) substrate, a silicon nitride (Si₃N₄) layer of 1 nm or thicker in thickness formed on the silicon substrate, single-crystal aluminum nitride (AlN) layer formed on the silicon nitride layer, and a single-crystal layer containing gallium (Ga) formed on the aluminum nitride layer. It is to be noted that the amount ratio of silicon to nitrogen of the con nitride layer may be 3:4 or may be a different value.

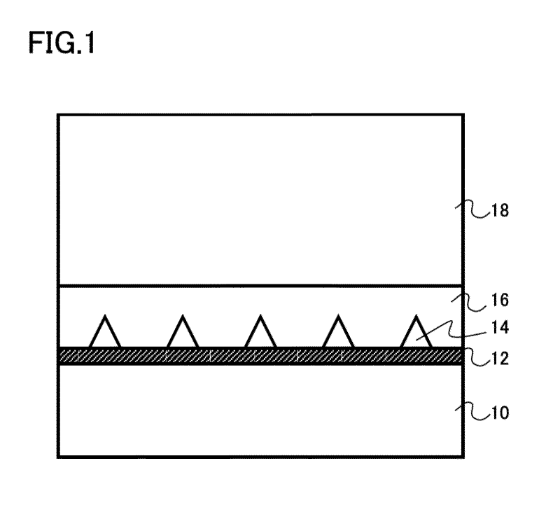

FIG. 1 is a schematic cross-sectional view of a semiconductor substrate according to the first embodiment.

The semiconductor substrate according to the first embodiment includes a silicon (Si) substrate 10, a silicon nitride (Si₃N₄) layer 12 of 1 nm oz thicker in layer thickness formed on the silicon substrate 10, single-crystal aluminum nitride (AlN) layer 14 formed on the silicon nitride layer 12, a single-crystal aluminum gallium nitride (AlₓGa₍₁₋ₓ₎N) layer 16 formed over the aluminum nitride layer 14, and a gallium nitride (GaN) layer 18 formed on the aluminum gallium nitride layer 16.

The silicon (Si) substrate 10 is, for example, a silicon substrate with a (111) plane surface. The silicon substrate 10 may have a surface that is offset from the (111) plane at an angle that is not greater than 10 degrees.

The silicon nitride (Si₃N₄) layer 12 is formed on the silicon substrate 10. The silicon nitride layer 12 has a thickness of 1 nm or thicker. It is to be noted that the amount ratio of silicon to nitrogen of the silicon nitride layer may be 3:4 or may be a different value.

The silicon nitride layer 12 acts to suppress reaction between silicon and gallium to cause degradation in layer quality of the single-crystal layer containing gallium (Ga) or meltback of the silicon substrate in epitaxially growing the single-crystal layer containing gallium (Ga) on the silicon substrate 10. From the viewpoint of suppressing reaction between silicon and gallium, the layer thickness is desirably not thinner than 1 nm.

On the other hand, setting too thick for the silicon nitride layer 12 leads to difficulty in forming the silicon nitride layer 12. Further, warpage of the semiconductor substrate may be increased due to stress originating from the silicon nitride layer 12. In view of these points, the silicon nitride layer 12 desirably has a layer thickness that is not thicker than 10 nm.

The single-crystal aluminum nitride layer 14 is formed on the silicon nitride layer 12. According to the first embodiment, the aluminum nitride layer 14 is grown in island growth and not as a continuous layer on the silicon nitride layer 12. The aluminum nitride layer 14 may be formed before the formation of the silicon nitride layer 12. The aluminum nitride layer 14 is in a form of islands.

The single-crystal aluminum gallium nitride layer 16 is formed over the aluminum nitride layer 14 and on the silicon nitride layer 12. The aluminum gallium nitride layer 16 is an example of the single-crystal layer containing gallium. According to the first embodiment, an example is given in which the aluminum gallium nitride layer makes a continuous layer. For example, however, the aluminum gallium nitride layer may be grown in island growth.

The single-crystal gallium nitride layer 18 is formed on the aluminum gallium nitride layer 16. It is to be noted that another single-crystal layer such as a single-crystal aluminum gallium nitride (AlₓGa₍₁₋ₓ₎N) layer may be further formed on the gallium nitride layer 18.

It is to be noted that the aluminum nitride layer 14 and the aluminum gallium nitride layer 16 function as a buffer layer for buffering lattice mismatch between the gallium nitride layer 18 and the silicon substrate 10. According to the first embodiment, an example is described in which the aluminum nitride layer 14 is grown in island growth and a layer of aluminum gallium nitride layer 16 are provided, but the configuration of the buffer layer is not limited thereto. For example, the buffer layer may have an alternate structure comprising a plurality of stacks in which a gallium nitride layer, an aluminum gallium nitride layer, and an aluminum nitride layer are placed on each other.

The structure of the semiconductor substrate according to the first embodiment may be adopted, so as to suppress reaction between silicon and gallium by the silicon nitride layer 12, thus facilitating formation of a high-quality single-crystal layer containing gallium on the silicon substrate 10. Further, since the silicon nitride layer 12 suppresses reaction between silicon and gallium, for example, formation of a thick aluminum nitride layer for suppressing reaction between silicon and gallium may be skipped before the formation of the single-crystal layer containing gallium. Hence, a margin for controlling warpage of the semiconductor substrate is increased. Further, the silicon nitride layer 12 of 1 nm or larder in thickness increases the insulation property, thus improving the pressure resistance of the semiconductor device to be manufactured with the semiconductor substrate according to the first embodiment.

Next, description is given of a method of manufacturing the semiconductor substrate according to the first embodiment . The semiconductor substrate according to the first embodiment is formed by way of the metalorganic chemical vapor deposition (MOCVD) method. For example, the semiconductor substrate is formed by using a vertical, single wafer type epitaxial apparatus.

The method of manufacturing the semiconductor substrate according to the first embodiment includes forming single-crystal aluminum nitride layer on a silicon substrate, nitriding the silicon substrate to forma silicon nitride layer between the aluminum nitride layer and the silicon substrate, which silicon nitride layer is adapted to have a layer thickness of 1 nm or larger, and forming a single-crystal layer containing gallium (Ga) over the aluminum nitride layer.

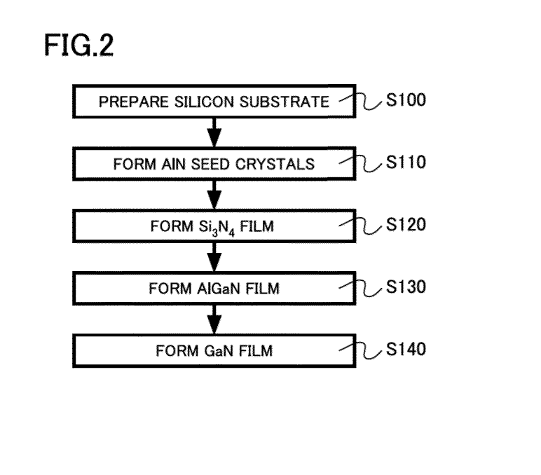

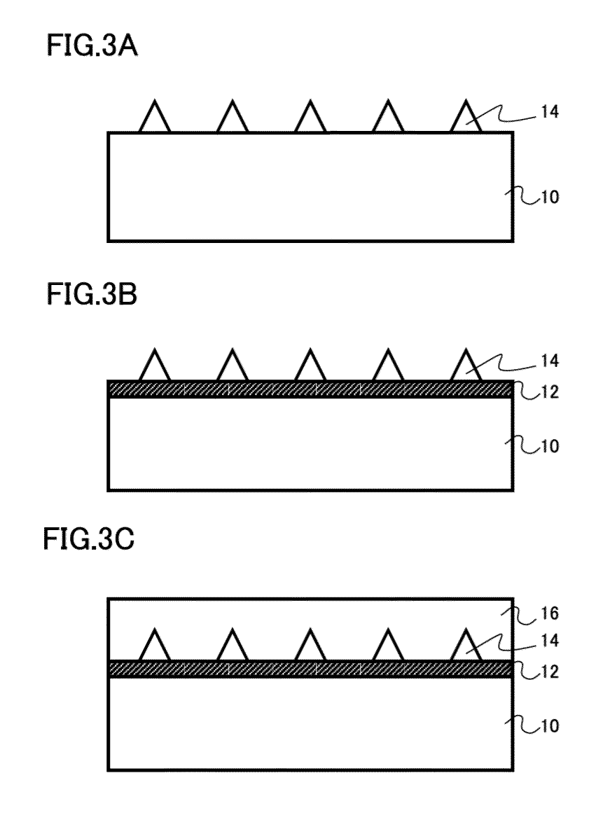

First, description is given of a first manufacturing method according to the first embodiment. FIG. 2 is a process flow diagram of the first manufacturing method according to the first embodiment. Further, FIGS. 3A to 3C are schematic cross-sectional views depicting the first manufacturing method according to the first embodiment.

The first manufacturing method according to the first embodiment includes preparing a silicon substrate (S100), forming aluminum nitride (AlN) seed crystals (S110), forming a silicon nitride (Si₃N₄) layer (S120), forming an aluminum gallium nitride (AlGaN) layer (S130), and forming a gallium nitride (GaN) layer (S140).

First, for example, a silicon substrate 10 of a (111) plane is prepared by performing baking in hydrogen (111) at 1100° C. to remove a native oxide (S100). Then, aluminum nitride (AlN) seed crystals 14 are grown in island growth on the silicon substrate 10 (S110; FIG. 3A).

The aluminum nitride seed crystals 14 are epitaxially grown on the silicon substrate 10. The silicon substrate 10 is heated, and the aluminum nitride seed crystals 14 are grown with, for example, trimethylaluminum (TMA) diluted with hydrogen (H₂) and ammonia (NH₃) diluted with hydrogen (H₂) being supplied as source gas. TMA is a source for aluminum (Al), and ammonia is a source for nitrogen (N).

Next, a silicon nitride (Si₃N₄) layer 12 is formed between the aluminum nitride (AlN) seed crystals 14 and the silicon substrate 10 (S120; FIG. 3B). The silicon nitride layer 12 is formed by heating the silicon substrate 10 and supplying, for example, ammonia (NH₃) diluted with hydrogen (H₂) to nitride the silicon substrate 10.

Next, an aluminum gallium nitride (AlₓGa₍₁₋ₓ₎N) layer 16 is epitaxially grown on the aluminum nitride seed crystals 14 with the aluminum nitride seed crystals 14 serving as nuclei of growth (S130; FIG. 3C). The aluminum gallium nitride layer 16 is an example of the single-crystal layer containing gallium.

The aluminum gallium nitride layer 16 is grown by heating the silicon substrate 10 and supplying, for example, trimethylaluminum (TMA) and trimethylgallium (TMG) that are diluted with hydrogen (H₂) and ammonia (NH₃) diluted with hydrogen (H₂) as source gas. TMA is a source tor aluminum (Al), TMG is a source for gallium (Ga), and ammonia is a source for nitrogen (N).

Next, a gallium nitride (GaN) layer 18 is epitaxially grown on the aluminum gallium nitride layer 16, such that the semiconductor substrate depicted in FIG. 1 is manufactured. The gallium nitride layer 18 is grown by heating the silicon substrate 10 and supplying, for example, trimethylgallium (TMG) diluted with hydrogen (H₂) and ammonia (NH₃) diluted with hydrogen (H₂) as source Gas. TMG is a source for gallium (Ga), and ammonia is a source for nitrogen (N).

According to the method of manufacturing the semiconductor substrate of the first embodiment, since the silicon nitride layer 12 suppresses reaction between silicon and gallium, a high-quality single-crystal layer containing gallium is easily formed on a silicon substrate. Further, since the silicon nitride layer 12 suppresses reaction between silicon and gallium, for example, formation of a thick aluminum nitride layer for suppressing reaction between silicon and gallium may be skipped before the formation of the single-crystal layer containing gallium.

Further, the aluminum gallium nitride layer 16 is epitaxially grown over the aluminum nitride seed crystals 14 in the form of islands. Hence, since the origins for nucleation of the aluminum gallium nitride layer 16 are limited, density of boundaries between aluminum gallium nitride is decreased in the growth process. Thus, defective density originating from the boundaries is reduced. Hence, a high-quality single-crystal layer is formed. Further, a direction of dislocation is made oblique, therefore, dislocation is reduced as the gallium nitride layer 18 grows.

It is to be noted that trimethylaluminum (TEA) may be exemplarily applied as a source for aluminum (Al), trimethylgallium (TEG) may be exemplarily applied as a source for gallium (Ga), and monomethylhydrazine or dimethylhydrazine may be exemplarily applied as a source for nitrogen (N).

Further, for example, a thin, aluminum-seed or two or less atom-thick silicon nitride layer may be formed before growing the aluminum nitride seed crystals 14. This silicon nitride layer, however, has a layer thickness that does not prevent the aluminum nitride seed crystals 14 from growing as single crystals. In case where aluminum seeds are grown, trimethylaluminum is supplied. The aluminum seeds turn into aluminum nitride layer in the form of islands upon reacting with ammonia at a later stage where the aluminum nitride is grown. In case where a thin, two or less atom-thick silicon nitride layer is grown, ammonia is supplied.

As described above, the silicon nitride layer 12 desirably has a thickness in a range from 1 nm to 10 nm.

Further, another single-crystal layer such as a single-crystal aluminum gallium nitride layer may be further formed on the gallium nitride layer 18.

Further, gallium nitride may be epitaxially grown as the single-crystal layer containing gallium on the aluminum nitride seed crystals 14.

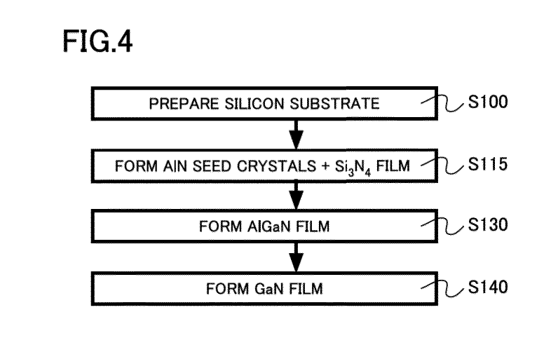

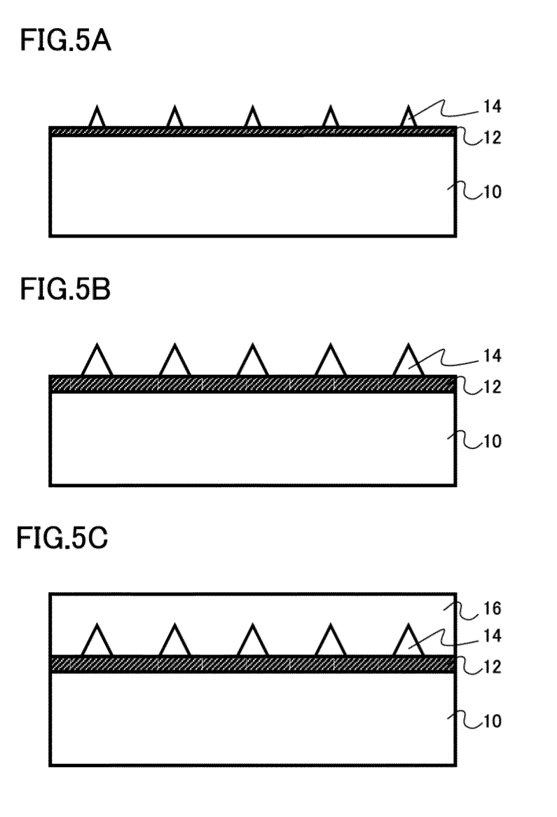

Next, description is given of a second manufacturing method according to the first embodiment. FIG. 4 is a process flow diagram of the second manufacturing method according to the first embodiment. Further, FIGS. 5A to 5C are schematic cross-sectional views depicting the second manufacturing method according to the first embodiment.

The second manufacturing method according to the first embodiment includes preparing a silicon (Si) substrate (S100), forming aluminum nitride (AlN) seed crystals and a silicon nitride (Si₃N₄) layer (S115), forming an aluminum gallium nitride (AlGaN) layer (S130), and forming a gallium nitride (GaN) layer (S140). The method is the same as the first manufacturing method except that the aluminum nitride seed crystals and the silicon nitride layer are formed simultaneously. Hence, description is partially not given to avoid redundant description for the details overlapping those of the first manufacturing method.

First, for example, a silicon substrate 10 of a (111) plane is prepared (S100). Then, aluminum nitride (AlN) seed crystals 19 are grown in island growth on the silicon substrate 10, when a silicon nitride (Si₃N₄) layer 12 is formed between the aluminum nitride seed crystals 14 and the silicon substrate 10 simultaneously (S115; FIG. 5A).

The aluminum nitride seed crystals 14 are epitaxially grown on the silicon substrate 10. The silicon substrate 10 is heated, and the aluminum nitride seed crystals 14 are grown with, for example, trimethylaluminum (TMA) diluted with hydrogen (H₂) and ammonia (NH₃) diluted with hydrogen (H₂) being supplied as source gas. TMA is a source for aluminum (Al), and ammonia is a source for nitrogen (N).

At this point, the silicon substrate 10 is nitrided by ammonia of the source gas, such that a silicon nitride layer 12 is formed between the aluminum nitride seed crystals 14 and the silicon substrate 10. The flow rates of TMA and ammonia are adjusted so as to form the aluminum nitride seed crystals 14 and the silicon nitride layer 12 simultaneously. More specifically, the flow rates of TMA and ammonia are adjusted, such that the growth of aluminum nitride layer and the nitriding of silicon simultaneously occur in a competitive manner. The flow rate ratio or ammonia to TMA (V/III ratio) is increased as compared with a regular condition for forming an aluminum nitride single crystal layer, such that the nitriding rate of silicon is increased.

The source gas is supplied under a condition where the flow rates of TMA and ammonia are appropriately controlled, such that the aluminum nitride seed crystals 14 are grown as the silicon nitride layer 12 gains thickness to have a layer thickness of not thinner than 1 nm (FIG. 5B).

After that, an aluminum gallium nitride film 16 is epitaxially grown over the aluminum nitride seed crystals 14 (S130; FIG. 5C).

According to the second manufacturing method, the semiconductor substrate depicted in FIG. 1 is manufactured through even simpler processes as compared with the first manufacturing method.

### Second Embodiment

A semiconductor substrate according to a second embodiment is the same as that of the first embodiment except that the aluminum nitride layer is grown in laminar growth on the silicon substrate and not drown in island growth. Hence, description is partially not given to avoid redundant description for the details overlapping those of the first embodiment.

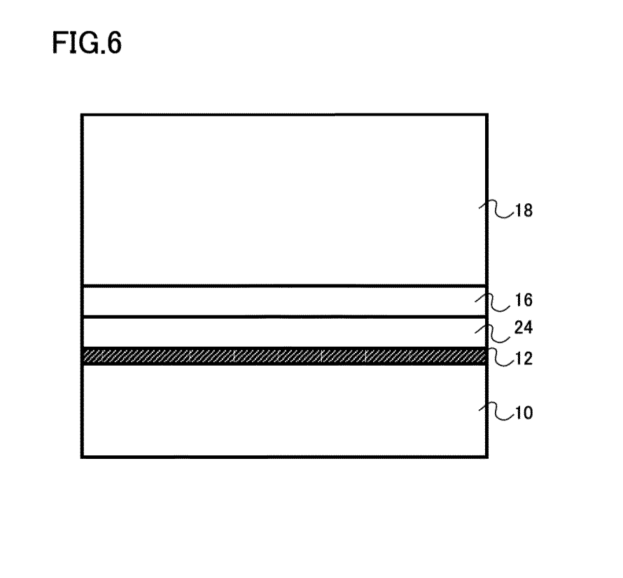

FIG. 6 is a schematic cross-sectional view of the semiconductor substrate according to the second embodiment.

The semiconductor substrate according to the second embodiment includes a silicon (Si) substrate 10, a silicon nitride (SiN) layer 12 of 1 nm or thicker in layer thickness disposed on the silicon substrate 10, a single-crystal aluminum nitride (AlN) layer 24 disposed on the silicon nitride layer 12, a single-crystal aluminum gallium nitride (AlGaN) layer 16 disposed on the aluminum nitride layer 24, and a gallium nitride (GaN) layer 18 disposed on the aluminum gallium nitride layer 16.

The silicon (Si) substrate 10 is, for example, a silicon substrate with a (111) plane surface. The silicon nitride (Si₃N₄) layer 12 is disposed on the silicon substrate 10. The silicon nitride layer 12 has a thickness that is not thinner than 1 nm.

The single-crystal aluminum nitride (AlN) layer 24 is disposed on the silicon nitride layer 12. According to the second embodiment, the aluminum nitride layer 24 is provided as a continuous layer over the silicon nitride layer 12.

The single-crystal aluminum gallium nitride (AlGaN) layer 16 is formed on the aluminum nitride layer 24. The aluminum gallium nitride layer 16 is an example of the single-crystal layer containing gallium (Ga).

The single-crystal gallium nitride (GaN) layer 18 is formed on the aluminum gallium nitride layer 16. It is to be noted that another single-crystal layer such as a single-crystal aluminum gallium nitride (AlGaN) layer may be further formed on the gallium nitride layer 18.

It is to be noted that the aluminum nitride layer 24 and the aluminum gallium. nitride layer 16 function as a buffer layer for buffering lattice mismatch between the gallium nitride layer 18 and the silicon substrate 10. According to the second embodiment, description is given of an example in which a layer of aluminum nitride layer 29 and a layer of aluminum gallium nitride layer 16 are provided, but the configuration of the buffer layer is not limited thereto. For example, the buffer layer may have an alternate structure comprising a plurality of stacks in which an aluminum gallium nitride layer is placed on an aluminum nitride layer.

Similar effects as those of the first embodiment are achieved by adopting the structure of the semiconductor substrate according to the second embodiment. Further, since the aluminum nitride is formed in grown in laminar growth and not grown in island growth, controlling of the manufacturing process is facilitated.

Next, description is given of a method of manufacturing the semiconductor substrate according to the second embodiment. The semiconductor substrate according to the second embodiment is formed by way of the metalorganic chemical vapor deposition method (MOCVD method).

The method of manufacturing the semiconductor substrate according to the second embodiment includes forming a single-crystal aluminum nitride layer on a silicon substrate, nitriding the silicon substrate to forma silicon nitride layer of 1 nm or thicker in layer thickness between the aluminum nitride layer and the silicon substrate, and forming a single-crystal layer containing gallium (Ga) on the aluminum nitride layer. The method is the same as the first manufacturing method according to the first embodiment except that aluminum nitride layer is grown in laminar growth and not grown in island growth on the silicon substrate. Hence, description is partially not given to avoid redundant description for the details overlapping those of the first manufacturing method according to the first embodiment.

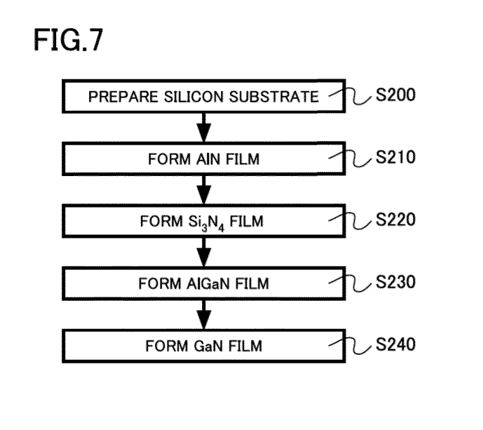

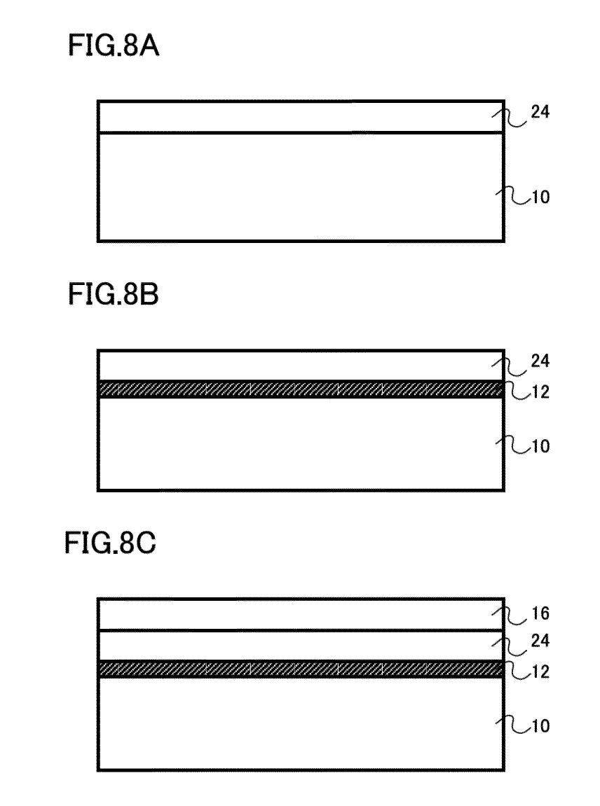

FIG. 7 is a process flow diagram of the manufacturing method according to the second embodiment. Further, FIGS. 8A to 8C are schematic cross-sectional views depicting the manufacturing method according to the second embodiment.

The manufacturing method according to the second embodiment includes preparing a silicon (Si) substrate (S200), forming an aluminum nitride (AlN) layer (S210), forming a silicon nitride (Si₃N₄) layer (S220), forming an aluminum gallium nitride (AlₓGa₍₁₋ₓ₎N) layer (S230), and forming a gallium nitride (GaN) layer (S240).

First, for example, a silicon substrate 10 of a (111) plane is prepared by performing baking in hydrogen (H₂) at 1100° C. (S200) to remove a native oxide (S200). Then, an aluminum nitride (AlN) layer 24 is formed on the silicon substrate 10 (S210; FIG. 8A).

The aluminum nitride layer 24 is epitaxially grown on the silicon substrate 10. The aluminum nitride layer 24 has a layer thickness that is set so as to allow nitrogen to permeate to the silicon substrate at a later stage where a silicon nitride layer 12 is formed.

Next, a silicon nitride layer 12 is formed between the aluminum nitride layer 24 and the silicon substrate 10 (S220; FIG. 8B). The silicon nitride layer 12 is formed by heating the silicon substrate 10 and nitriding the silicon substrate 10 with, for example, ammonia (NH₃) diluted with hydrogen (H₂) being supplied. Nitrogen is diffused within the aluminum nitride layer 24, and the silicon substrate 10 is nitrided.

Next, an aluminum gallium nitride (AlGaN) layer 16 is epitaxially grown on the aluminum nitride layer 24 (S230; FIG. 8C). The aluminum gallium nitride layer 16 is an example of the single-crystal layer containing gallium (Ga).

Next, a gallium nitride (GaN) layer 18 is epitaxially grown on the aluminum Gallium nitride layer 16, such that the semiconductor substrate depicted in FIG. 6 is manufactured (S240).

According to the method of manufacturing the semiconductor substrate according to the second embodiment, similar effects as those of the first embodiment are achieved. Further, since aluminum nitride film is grown in laminar growth and not grown in island growth, controlling of the manufacturing process is facilitated.

It is to be noted that according to the second embodiment also, the aluminum nitride layer 24 and the silicon nitride layer 12 may be formed simultaneously as in the second manufacturing method according Lo the first embodiment.

### Third Embodiment

A semiconductor device according to a third embodiment includes a silicon substrate, a silicon nitride layer of 1 nm or thicker in layer thickness formed on the silicon substrate, single-crystal aluminum nitride layer formed on the silicon nitride layer, and a single-crystal layer containing gallium (Ga) formed on the aluminum nitride layer. The semiconductor device according to the third embodiment includes the semiconductor substrate according to the first embodiment. Hence, description is partially not given to avoid redundant description for the details overlapping those of the first embodiment.

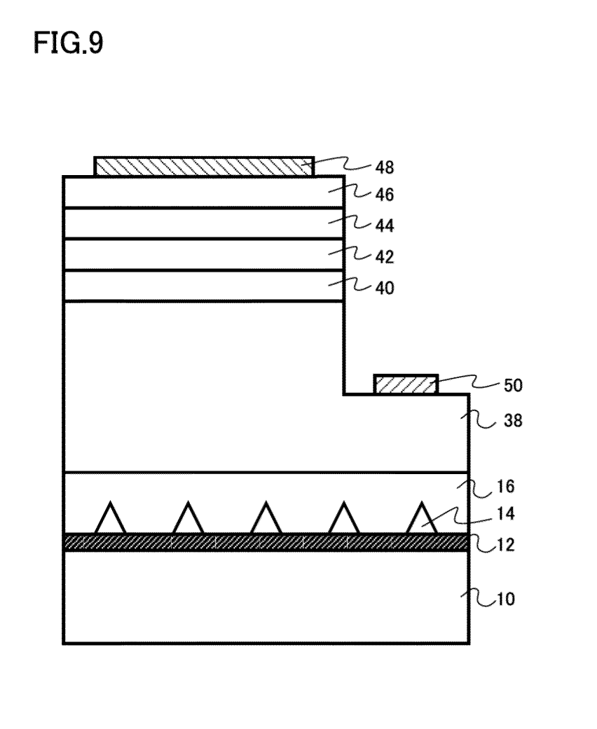

FIG. 9 is a schematic cross-sectional view of the semiconductor device according to the third embodiment. The semiconductor device according to the third embodiment is a light emitting diode (LED) configured to emit blue light.

The semiconductor device according to the third embodiment includes a silicon Si) substrate 10, a silicon nitride Si₃N₄) layer 12 of 1 nm or thicker in layer thickness formed on the silicon substrate 10, single-crystal aluminum nitride (AlN) layer 14 formed on the silicon nitride layer 12, a single-crystal aluminum gallium nitride (AlₓGa₍₁₋ₓ₎N) layer 16 formed over the aluminum nitride layer 14, and an n-type gallium nitride (GaN) layer 38 formed on the aluminum gallium nitride layer 16. Moreover, the semiconductor device further includes an n-type aluminum gallium nitride (AlₓGa₍₁₋ₓ₎N) layer 40, an active layer 42, a p-type aluminum gallium nitride (AlₓGa₍₁₋ₓ₎N) layer 44, and a p-type gallium nitride (GaN) layer 46 that are on the n-type gallium, nitride (GaN) layer 38.

Further, an n-side electrode 50 is positioned on the n-type gallium nitride (GaN) layer 38. A p-side transparent electrode 48 is positioned on the p-type gallium nitride (GaN) layer 46.

The active layer 42 has, for example, a multiple quantum well structure. The active layer 42 has, for example, a structure having, for example, an indium gallium nitride (In_{y}Ga₍₁₋ₓ₎N) layer and a gallium nitride (GaN) layer alternatively stacked on each other.

The semiconductor device according to the third embodiment emits blue light upon passing electricity between the p-side transparent electrode 48 and the n-side electrode 50. The semiconductor device may be peeled off from the silicon substrate 10 and be mounted on a highly reflective metal.

According to the third embodiment, a high-quality single-crystal layer containing gallium is easily formed on the silicon substrate 10. Hence, an LED with a better light-emitting property is easily made.

### Example

An example of the present disclosure is described below.

### Example

A semiconductor substrate was manufactured through the same processes as those of the second manufacturing method according to the first embodiment. Aluminum nitride seed crystals and a silicon nitride layer were formed simultaneously on a silicon substrate of a (111) plane in a reaction chamber of a vertical, single wafer type epitaxial apparatus. Thickness in a range from 3 nm to 4 nm was set for the silicon nitride layer.

In so doing, the silicon substrate was heated in hydrogen to 1100° C. to remove a native oxide, and then the silicon substrate was heated to 1000° C. and the pressure inside the reaction chamber was brought to 26.6 kPa. Three sccm of trimethylaluminum (TMA), 15 slm of ammonia (NH₃), and 60 slm of hydrogen (H₂) were supplied as source gas.

Next, an aluminum gallium nitride layer was formed over the aluminum nitride seed crystals and the silicon nitride layer. TMA and TMG diluted with hydrogen and ammonia diluted with hydrogen were used as source gas.

After that, a gallium nitride layer was formed on the aluminum gallium nitride layer. TMG diluted with hydrogen and gaseous ammonia diluted with hydrogen were used as source gas.

### Comparative Example

Film formation was performed in a similar manner to Example except that the silicon substrate was nitrided with ammonia diluted with hydrogen to form a silicon nitride layer before forming aluminum nitride seed crystals. In so doing, a thickness in a range from 3 nm to 4 nm was set for the silicon nitride layer.

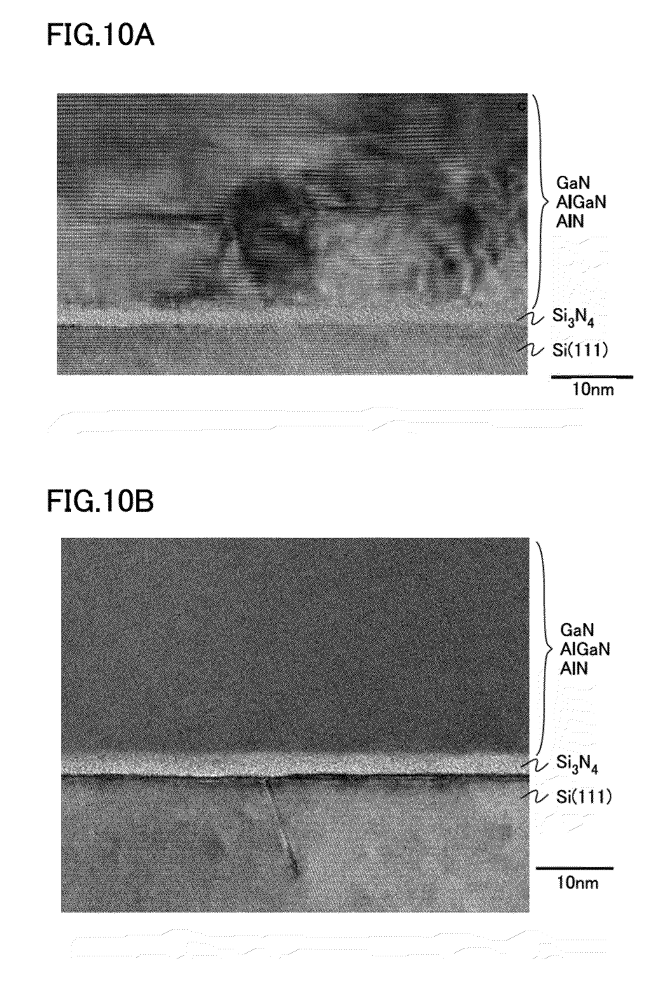

With respect to each of Example and Comparative Example, a cross section of the semiconductor substrate after the layer formation was observed with a transmission electron microscope (TEM). FIGS. 10A and 10B are cross-sectional TEM photos of Example and Comparative Example. FIG. 10A is Example, and FIG. 10B is Comparative Example.

In case of Example, it is seen that the AlN, AlGaN layer, and GaN layer on the silicon nitride (Si₃N₄) layer are single crystal line because of the observability of a crystal lattice image. Further, a phenomenon was not confirmed in which reaction between silicon con and gallium caused degradation in quality of the single-crystal layer or meltback of the silicon substrate upon reacting with Ga.

Meanwhile, a crystal lattice image was not observed with respect to Comparative Example. It is seen that the AlN, AlGaN layer, and GaN layer are not single-crystalline but amorphous or polycrystalline. In case of Comparative Example, the reason is considered that the silicon nitride layer has a thicker thickness, and that aluminum nitride (AlN) layer did not epitaxially grow on the silicon nitride layer.

It was made clear by Example that reaction between silicon and gallium is suppressible, and a high-quality single-crystal layer containing gallium is formable, by forming a silicon nitride layer of 1 nm or thicker between the single-crystal aluminum nitride layer and the silicon con substrate.

In the foregoing description, embodiments of the present invention are described with reference to specific examples. The above embodiments are described by way of example and are not intended to restrict the present invention. Further, components of the embodiments may be appropriately combined.

In the embodiments, description is not given for parts and portions which are not directly relevant to the description of the present disclosure for, for example, the semiconductor substrate, method of manufacturing the semiconductor substrate, and semiconductor device; however, a semiconductor substrate, or a configuration of a semiconductor device or a manufacturing method thereof may be appropriately selected for use as needed.

In addition, the scope of the present disclosure encompasses any semiconductor substrate, method of manufacturing the semiconductor substrate, and semiconductor device that include elements of the present disclosure and that is of an appropriate design choice for those skilled in the art. The scope of the present disclosure is defined by the appended claims and equivalents thereof.

What is claimed is:

1. A semiconductor substrate comprising:
a silicon substrate;
a silicon nitride layer on the silicon substrate, the silicon nitride layer having a thickness of 1 nm or thicker;
single-crystal aluminum nitride layer on the silicon nitride layer; and
a single-crystal layer on the aluminum nitride layer, the single-crystal layer containing gallium (Ga).

2. The semiconductor substrate according to claim 1, wherein the aluminum nitride layer is grown in island growth on the silicon nitride layer.

3. The semiconductor substrate according to claim 1, wherein the aluminum nitride layer is grown in laminar growth on the silicon nitride layer.

4. The semiconductor substrate according to claim 1, wherein the single-crystal layer containing gallium (Ga) is gallium nitride or aluminum gallium nitride.

5. A semiconductor device comprising:
a silicon substrate;
a silicon nitride layer on the silicon substrate, the silicon nitride layer having a thickness of 1 nm or thicker;
single-crystal aluminum nitride layer on the silicon nitride layer; and
a single-crystal layer on the aluminum nitride layer, the single-crystal layer containing gallium (Ga).

6. The semiconductor device according to claim 5, wherein the aluminum nitride layer is grown in island growth on the silicon nitride layer.

7. The semiconductor device according to claim 5, wherein the aluminum nitride layer is grown in laminar growth on the silicon nitride layer.

8. The semiconductor device according to claim 5, wherein the single-crystal layer containing gallium (Ga) is a gallium nitride (GaN) layer or an aluminum gallium nitride layer.

9. The semiconductor device according to claim 5, further comprising:
an n-type gallium nitride layer on the single-crystal layer containing gallium (Ga);
an active layer on the n-type gallium nitride layer, the active layer having a multiple quantum well structure; and
a p-type gallium nitride layer on the active layer.

10. A method of manufacturing a semiconductor substrate, the method comprising:
forming single-crystal aluminum nitride layer on a silicon substrate;
nitriding the silicon substrate to form a silicon nitride layer between the aluminum nitride layer and the silicon substrate, the silicon nitride layer having a thickness of 1 nm or thicker; and
forming a single-crystal layer containing gallium (Ga) on the aluminum nitride layer.

11. The method of manufacturing a semiconductor substrate according to claim 10, wherein the aluminum nitride layer is grown in island growth on the silicon substrate.

12. The method of manufacturing a semiconductor substrate according to claim 10, wherein the aluminum nitride layer is grown in laminar growth on the silicon substrate.

13. The method of manufacturing a semiconductor substrate according to claim 10, further comprising forming an aluminum seed on the silicon substrate before forming the aluminum nitride layer on the silicon substrate.

14. The method of manufacturing a semiconductor substrate according to claim 10, further comprising forming a two or less atom-thick silicon nitride layer on the silicon substrate before forming the aluminum nitride layer on the silicon substrate.

15. The method of manufacturing a semiconductor substrate according to claim 10, wherein the silicon nit layer has a thickness of 10 nm or thinner.

16. The method of manufacturing a semiconductor substrate according to claim 10, wherein the single-crystal aluminum nitride layer and the silicon nitride layer are formed simultaneously.
